(19) United States
(12) Patent Application Publication
(10) Pub. No.: US 2004/0026121 A1
(43) Pub. Date: Feb. 12, 2004

(54) Electrode and/or conductor track for organic components and production method thereof

(76) Inventors: Adolf Bernds, Baiersdorf (DE); Wolfgang Clemens, Puschendorf (DE); Walter Fix, Furth (DE); Henning Rost, Erlangen (DE)

Correspondence Address: YOUNG & THOMPSON, 745 SOUTH 23RD STREET 2ND FLOOR, ARLINGTON, VA, 22202

(21) Appl. No.: 10/381,032

(22) PCT Filed: Sep. 20, 2001
(86) PCT No.: PCT/DE01/03645

(30) Foreign Application Priority Data
Sep. 22, 2000 (DE) 100 47 171.4
May 8, 2001 (DE) 101 22 213.0

(51) Int. Cl. H05K 1/09; H01B 5/00; B32B 3/10; G03F 7/20; G03F 7/30; G03F 7/40

(52) U.S. Cl. 174/257; 430/311; 430/313; 430/317; 430/319; 430/320; 174/126.2; 428/195.1

(57) ABSTRACT

The invention relates to electrodes for organic components, particularly for components such as field effect transistors (OFET's) and/or light-emitting diodes (OLED's), which have conductive and highly resolved finely structured electrode tracks. The electrode and/or conductor track are/is produced by treating a conductive or non-conductive layer comprised of an organic functional polymer with a chemical compound since, at the point of contact, the chemical compound deactivates or activates the layer comprised of an organic functional polymer, i.e. renders it conductive or non-conductive. The non-conductive regions of the layer can be removed.

The invention relates to an electrode and/or conductor track for organic elements, particularly elements for field effect transistors (OFETs), photoelectronic components and/or light emitting diodes (OLEDs), that are conductive and have finely structured electrode tracks.

Conductive electrode tracks on an organic base are known from “Lithographic patterning of conductive polyaniline” by T. Makela et al. in “Synthetic metals” 101, (1999), p. 705-706. This describes how a conductive polyaniline layer (PANI) is applied to a substrate and then covered with a positive photoresist layer. After drying, the photoresist layer is UV-irradiated through a shadow mask. The photoresist at the exposed areas is removed by an alkaline developer, which at the same by a chemical reaction, renders the exposed polyaniline at the irradiated areas non-conductive. The disadvantage of this method is that alkaline species from the areas treated with alkaline diffuse in time through the extremely thin conductive finger structures, partially deprotonize them and thus have a lasting negative effect on their conductivity.

It is also known from publication “Low-cost all polymer integrated circuits” by C. J. Dury et al. in “Applied Physics Letters” Vol. 73, No. 1, p. 108/110 that polyaniline together with a photoinitiator can be applied to the substrate, can in turn be irradiated through a shadow mask after drying and rendered non-conductive at the irradiated areas by chemical treatment.

The disadvantage of the aforementioned method with a photoresist layer or photoinitiator is that the method is relatively expensive because several work steps are required to create the electrodes, even with an existing layer of conductive organic material such as PANI.

The object of this invention is the rationalization of the process steps for creating long-life, highly resolved conductive tracks and/or electrodes of organic functional layers on a substrate.

The subject matter of the invention is an electrode and/or conductor track (2′) that can be produced by treating an organic functional polymer with a chemical compound. It is also an object of the invention to produce an electrode and/or a conductor track by treating an organic functional polymer with a chemical compound.

In accordance with an advantageous embodiment, the electrode and/or conductor track is produced by partial activation or deactivation of the organic functional polymer.

An advantageous embodiment of the invention is a method for producing highly resolved conductive structures on a substrate by applying a conductive organic layer and creating a non-conductive organic matrix in the conductive organic layer by structuring, that is characterized by the non-conductive matrix being then selectively removed by using a non-alkaline solvent or by oxidative etching.

In this way the conductive structures formed, i.e. webs or fingers on the substrate, are effectively protected from damage from alkaline species diffusing from the non-conductive areas. The formed structures are thus not air-sensitive, which means that a long service life is guaranteed for the all-organic, optoelectronic components such as field effect transistors (OFET) or light emitting diodes (OLED) produced from these.

In the context of this invention, a substrate is, for example, a flexible substrate such as a carrier film. It or a non-flexible substrate may, or may not, carry one or more functional layers.

The conductive organic layer is advantageously applied to the substrate by squeegee, spraying, spin-coating or by screen-printing. Because the polymer materials can be applied from solution, a particularly homogenous, thin layer is created by the latter method. The conductive organic polymer is preferably polyaniline doped, for example, with camphoric sulfonic acid (CSA). All conductive organic materials that are selectively deactivated can be used at this point. In particular, other conductive polymers can also be used, provided these are rendered non-conductive by the effect of an alkali or are oxidatively etched away.

In accordance with an embodiment, the non-conductive organic matrix is formed by deprotonizing the conductive layer in selected areas. To do this, the conductive layer is, for example, first produced from doped polyaniline (PANI) or from another conductive organic material such as polyethylenedioxythiophene (PEDOT). A thin layer of photoresist, preferably a positive photoresist, that is commercially available is created from this. The photoresist is rendered soluble to alkali in selected areas by structured exposure, for example by using a shadow mask, and these alkali-soluble areas are dissolved by an alkaline solvent.

It is advantageous with this method that the exposed polyaniline layer underneath is deprotonized by the alkaline solvent and thus becomes non-conductive. Liquid tetrabutylammonium compounds, or solutions of these, can be used as the alkaline solvent. Another alkaline solvent or developer is, for example, “AZ 1512 HS” (Merck).

The remaining photoresist is then dissolved using a suitable solvent such as low alcohols or ketones.

The dissolving-out of the non-conducting matrix can take place using a non-alkaline solvent either before or after this step. Dimethylformamide, that has already been freshly distilled, can in particular be used as the non-alkaline solvent. This guarantees that this solvent is free of amines. At the same time, it is guaranteed that deprotonizing of the fine conductive fingers by the amine is prevented. If this non-conductive matrix is not, for example, oxidative, this step must be carried out before removal of the photoresist.

In accordance with an advantageous embodiment of the invention, the organic functional layer is conductive and applied evenly over the substrate. This layer of organic functional polymer is rendered non-conductive at the areas at which it is treated with the chemical compound.

In accordance with one embodiment, the organic functional polymer is treated by printing with a chemical compound. Preferred printing methods for this are (arranged in accordance with increasing resolution) offset printing, screen-printing, tampon printing and/or micro-contact printing (μCP printing).

Printing with the chemical compound produces a drastic change in the conductivity of the organic functional polymer. This printing technique enables a fine structuring of the functional layer to be achieved. The resolution in this case depends on the efficiency of the particular printing method.

Printing can, for example, be carried out by a stamp, as with tampon printing or by means of a stamping roller using a continuous process.

In accordance with one embodiment (micro-contact printing), the chemical compound that activates or deactivates the organic functional polymer is absorbed into the stamp. In this case, the stamp can consist of an absorbent silicon elastomer.

The chemical compound is preferably an alkali, such as an amine, a hydroxide etc. In principle, all alkalis can be used, particularly those that deprotonize.

The term “organic material” or “organic functional polymer” in this case includes all types of organic, metal-organic and/or organic-anorganic synthetic materials (hybrids), particularly those known in English as “plastics”. This can include all kinds of materials, with the exception of semiconductors, that form the conventional diodes (germanium, silicon) and the typical metallic conductors. A limitation in the dogmatic sense, to organic material as a material containing carbon is accordingly not envisaged, but rather also includes the wide use of silicones, for example. Furthermore, the term should not be subject to any limitation with regard to the molecule size, particularly for polymer and/or oligomer materials, instead the use of “small molecules” is also entirely possible. The word element “polymer” in functional polymers is historically determined and to this extent gives no indication regarding the presence of an actual polymer compound.

For the method, a thin layer of conductive polyaniline is created, e.g. on a substrate (plastic, glass etc.) by pouring, spin coating, squeegee etc. Printing with an alkaline compound (amine, hydroxide) deprotonizes the PANI at the contact point with the alkaline, which thus loses its conductivity. After the electrode and/or conductor track has been produced, the complete layer is again rinsed and dried and thus fixed. Non-protonized, non-conducting areas of the functional polymer can be selectively removed by the subsequent rinsing.

It is also possible, as for printing the areas that are to be rendered non-conducting, to print only the thin conductive finger areas that produce electrode/conductor tracks.

It is also possible to combine the printing process with irradiation and/or exposure through a shadow mask.

The method in accordance with the invention is particularly suitable for producing organic field effect transistors (OFETs), organic light emitting diodes (OLEDs) or photoelectronic components, for which conductive and finely structured electrodes or electrode tracks are required.

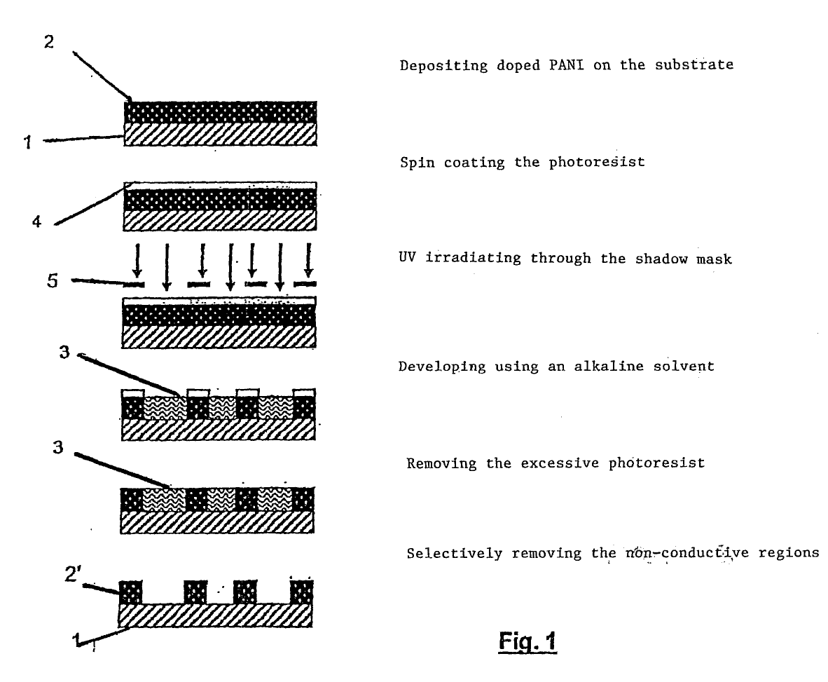

The method in accordance with the invention is explained in more detail in the following, with reference to the flowchart shown in the single FIG. 1, that illustrates only one embodiment of the invention.

First, a conductive layer 2 of polyaniline (PANI) doped with camphoric sulfonic acid (CSA) is homogeneously applied to a substrate 1, that for example consists of polyethylene, polyamide, but preferably polyterephthalate, film, for example by spin coating. A thin layer 4 of a positive photoresist is then applied to this conductive layer 2, again by spin coating for example, and is then exposed to UV light through a shadow mask 5. At the areas exposed to the light, the photoresist is made soluble by a chemical reaction, in this case particularly in an alkali. The complete substrate is then immersed in an alkali solvent, such as a tetrabutylammonium compound or AZ 1512 (Merck), so that the irradiated areas of the photoresist are dissolved. At the same time, the conductive polyaniline areas underneath, referred to as the PANI, come into contact with the alkaline solvent or developer, causing the PANI to be deprotonized and changed to a non-conductive modification, called the blue PANI. The photoresists are removed using a suitable solvent, preferably isopropanol. The substrate is then dipped in freshly distilled dimethylformamide (DMF), that is thus free of amines, causing the non-conductive matrix 3 to be dissolved. In this way, conductive PANI webs or electrodes or electrode tracks 2′ are produced in the structure predetermined by the shadow mask. If necessary, the substrate can also be placed for a short period in an aqueous solution of camphoric sulfonic acid (CSA), to saturate the surface of the PANI electrodes or electrode tracks with camphoric sulfonic acid, thus ensuring a high conductivity. The non-conductive matrix could also be dissolved by using dimethylformamide (DMF) already laced with camphoric sulfonic acid (CSA).

A further possibility is that the substrate can be immersed in a reactive etching solution after the development of the photoresist layer, so that exposed areas (3) can be oxidatively removed. This can be achieved, for example, by using a mixture consisting of 250 ml of concentrated sulfuric acid with an aqueous solution of 7.5 g of potassium permanganate in 100 ml of water.

Instead of a positive photoresist, a negative photoresist that is cross-linked by the UV radiation in the exposed areas can, of course, also be used. The non-exposed areas remain soluble and can be removed by a suitable solvent. Examples of suitable photoresist systems are described in Kirk-Othmer (3.) 17, pages 680 to 708.

By means of the method in accordance with the invention, reliable highly resolved conductive structures on substrates that have a long service life can thus be created.

The invention concerns electrodes for organic components, particularly for components such as field effect transistors (OFETs) and/or light emitting diodes (OLEDs), that have conductive, finely structured electrode tracks. The electrode/conductor track is produced by the simple contact between a conducting or non-conducting layer of organic material with a chemical compound, because the chemical compound activates or deactivates the layer of organic material at the contact point, i.e. renders it conducting or non-conducting.

1. Electrode and/or conductor track (2′) that can be produced by treating an organic functional polymer with a chemical compound.

2. Electrode and/or conductor track in accordance with claim 1, with the organic functional polymer being conductive before treatment with the chemical compound and present as a layer (2).

3. Electrode and/or conductor track in accordance with claim 1 or 2, with the organic functional polymer polyaniline being doped polyaniline or a different conductive organic material.

4. Electrode and/or conductor track in accordance with one of the preceding claims, with the chemical compound being an alkali or oxidating medium.

5. Electrode and/or conductor track in accordance with one of the preceding claims, that can be produced by selective removal of the areas (3) of the layer that are non-conducting after the treatment.

6. Electrode and/or conductor track in accordance with one of the preceding claims, with the affected areas (3) of the layer being deprotonized after treatment.

7. Method for producing an electrode and/or conductor track by treating an organic functional polymer with a chemical compound.

8. Method in accordance with claim 7, with the organic functional polymer being treated by printing with the chemical compound.

9. Method in accordance with one of claims 7 or 8, with the electrode and/or conductor track being produced by partial activation or deactivation of the organic functional polymer.

10. Method in accordance with one of claims 7 or 9, with a layer (2) of organic functional polymer being produced, and on this a layer (4) of photoresist being produced that is made soluble in selected areas by structured exposure, the soluble areas being removed, the exposed areas (3) then being either deprotonized by contact with alkali or etched off by contact with an oxidation agent and with the remaining photoresist then being dissolved in a further operation.

11. Method in accordance with claim 10, with the layer of organic functional polymer being produced by squeegee, spin coating, spraying or screen-printing.

12. Method in accordance with one of claims 10 or 11, with the soluble areas of the exposed photoresist being removed by means of an alkaline solvent that deprotonizes the areas (3) underneath at the same time as selectively removing the photoresist.

13. Method in accordance with claims 10 or 11, with a mixture of sulfuric acid with an aqueous potassium permanganate being used as the oxidation agent.

14. Method in accordance with one of claims 7 to 13 for the production of organic field effect transistors (OFETs).

15. Method in accordance with one of claims 7 to 14 for the production of organic light emitting diodes (OLEDs).

16. Method in accordance with one of claims 7 to 15 for the production of photoelectronic components.
